(19) United States
(12) Patent Application Publication
(10) Pub. No.: US 2024/0319586 A1
(43) Pub. Date: Sep. 26, 2024

(54) PATTERN DESIGN METHOD AND TEMPLATE MANUFACTURING METHOD

(71) Applicant: Kioxia Corporation, Tokyo (JP)

(72) Inventors: Yukichi KAMITA, Yokkaichi Mie (JP); Takahiro IWASAKI, Nagoya Aichi (JP)

(73) Assignee: Kioxia Corporation, Tokyo (JP)

(21) Appl. No.: 18/593,112

(22) Filed: Mar. 1, 2024

(30) Foreign Application Priority Data
Mar. 20, 2023 (JP) 2023-044103

(51) Int. Cl. G03F 7/00

(52) U.S. Cl. CPC G03F 7/0002

(57) ABSTRACT

An imprint method includes dividing an outer peripheral portion of a patterned surface including a device pattern into a plurality of regions along a circumferential direction. The imprint method includes disposing a dummy pattern in the outer peripheral portion, causing a pattern density of each of the plurality of regions to fall within a first range based on information regarding the device pattern.

### CROSS-REFERENCE TO RELATED APPLICATION (S)

This application is based upon and claims the benefit of priority from Japanese Patent Application No. 2023-044103, filed Mar. 20, 2023, the entire contents of which are incorporated herein by reference.

### FIELD

Embodiments described herein relate generally to a pattern design method and a template manufacturing method.

### BACKGROUND

Imprint lithography for forming an etching mask by pressing a template against a coating layer such as a resist layer is known. In imprint lithography, a coating layer may be formed on the entire surface of the etching target film by spin coating.

### DESCRIPTION OF THE DRAWINGS

FIGS. 1A to 1C are diagrams schematically illustrating a state in which a coating layer is imprinted using a template according to a first embodiment.

FIGS. 2A and 2B are diagrams schematically showing the template according to the first embodiment.

FIG. 3 is a plan view showing an example of a pattern density of projection portions in a plurality of small regions in the outer peripheral portion of the template according to the first embodiment.

FIG. 4 is a plan view showing an example of a pattern density of projection portions in a plurality of small regions in an outer peripheral portion in a template of a comparative example.

FIGS. 5A to 5C are diagrams schematically illustrating a state in which a coating layer is imprinted using the template of the comparative example.

FIG. 6 is a plan view showing an amount of a surplus resin extruded by performing imprint using the template of the comparative example.

FIG. 7 is a plan view showing an example of a state in which the surplus resin extruded by the template of the comparative example flows into a patterned region.

FIGS. 8A and 8B are diagrams showing an example in which a disposition state of a patterned region is changed according to a pattern density of the projection portion in the small region and a total volume of the projection portions.

### DETAILED DESCRIPTION

Embodiments provide a pattern design method and a template manufacturing method for reducing defects such as pattern filling with a resin of a coating layer.

In general, according to one embodiment, an imprint method of the embodiment includes dividing an outer peripheral portion of a patterned surface including a device pattern into a plurality of regions along a circumferential direction. The method includes disposing a dummy pattern in the outer peripheral portion, causing a pattern density of each of the plurality of regions to fall within a first range based on information regarding the device pattern.

Hereinafter, non-limiting embodiments will be described with reference to the accompanying drawings.

In all the accompanying drawings, the same or corresponding members or components are denoted by the same or corresponding reference numerals, and duplicate description thereof will be omitted. In addition, the drawings are not intended to show the relative thicknesses between members or components or between various layers. Therefore, specific thicknesses and dimensions may be determined by those skilled in the art with reference to the following non-limiting embodiments.

### First Embodiment

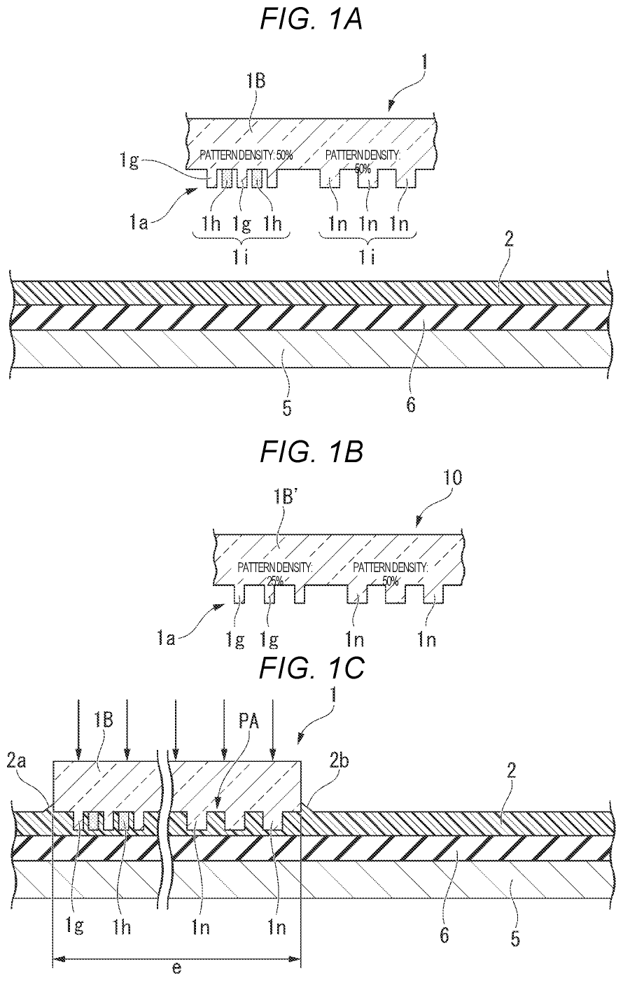

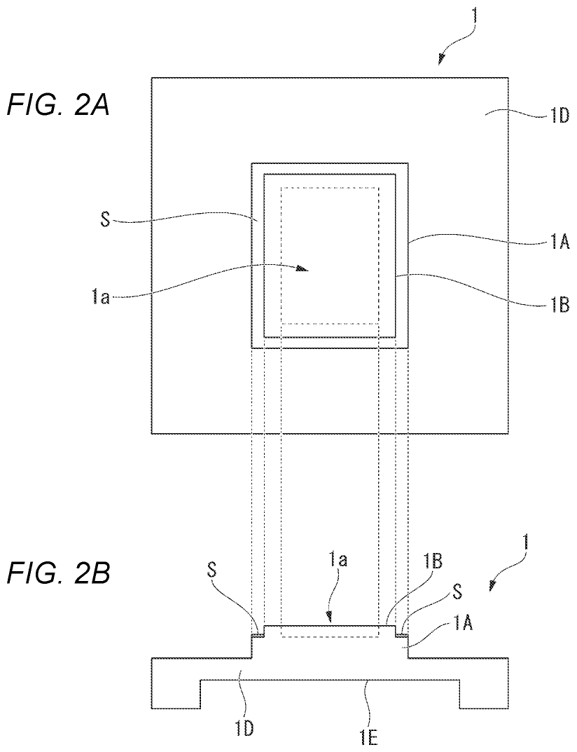

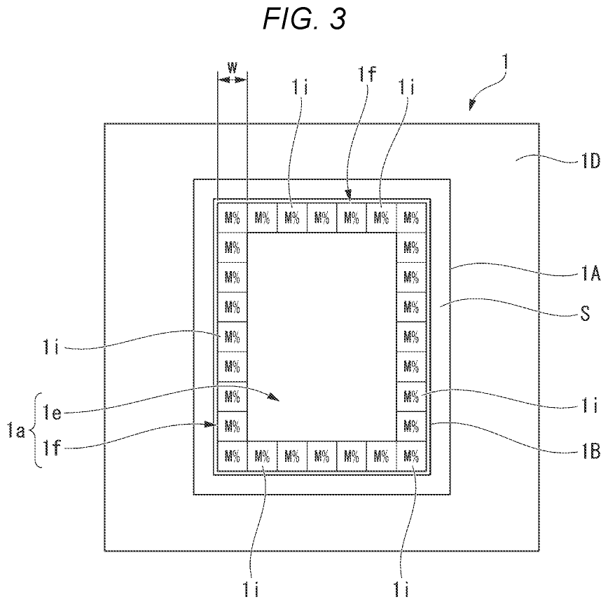

FIGS. 1A to 1C show a state in which an imprint method is performed on a coating layer 2 of a photocurable resin using a template 1 according to a first embodiment. A pattern of the template 1 of the present embodiment is manufactured using the pattern design method of the present embodiment. FIGS. 2A and 2B show an overall structure of the template 1, and FIG. 3 shows an example of a patterned surface formed on the template 1.

The coating layer 2 covers a target film 6 formed on one surface (upper surface) of a substrate 5 such as a semiconductor wafer shown in FIG. 1A. As an example, the coating layer 2 is a liquid layer before being formed on the target film 6 to a predetermined thickness by a coating method such as a spin coating method and being photocured as described below. The coating layer 2 is, for example, a photocurable resin or a resist. The target film 6 is not particularly limited, and examples thereof include an insulating layer such as silicon oxide, a conductive layer containing a metallic element, and a stacked film thereof. The template 1 is used to perform the imprint method on the coating layer 2 to form a desired uneven pattern on the coating layer 2, and the template 1 of the present embodiment is used to process such as etching the target film 6 using the uneven pattern.

The coating layer 2 may be directly formed on one surface (upper surface) of the substrate 5, or may be formed on an upper surface of the target film 6 formed on a stacked product (not shown) formed on the substrate 5. When the coating layer 2 is directly formed on the upper surface of the substrate 5, an uneven pattern is formed on the coating layer 2, and the upper surface of the substrate is processed such as etching using the uneven pattern. When the coating layer 2 is formed on the target film 6 on the upper surface of the stacked product on the substrate, an uneven pattern is formed on the coating layer 2, and the upper surface of the target film 6 is processed such as etching using the uneven pattern. The template 1 may be used in any case of the processing.

The template 1 is formed of a material capable of transmitting light (for example, ultraviolet rays), for example, quartz glass or a resin. As shown in FIGS. 2A and 2B, the template 1 includes a first mesa portion 1A and a second mesa portion 1B, and these masa portions are formed on one surface side of a plate-shaped substrate portion 1D. A recessed portion 1E is formed on the other surface side of the substrate portion 1D.

The imprint method can be performed by pressing the upper end surface of the second mesa portion 1B against the coating layer 2 formed on the upper surface side of the substrate 5 shown in FIG. 1A. In this case, the template 1 is disposed in an orientation inverted up and down with respect to the state shown in FIG. 2B. When the first mesa portion 1A and the second mesa portion 1B are turned upside down, the first mesa portion 1A and the second mesa portion 1B protrude on a lower surface side of the substrate portion 1D.

In FIGS. 1A to 1C, a state in which the template 1 shown in FIG. 2B is disposed upside down and a part of the upper end surface of the second mesa portion 1B is pressed against the coating layer 2 on the substrate 5 is shown.

In FIGS. 1A to 1C, the first mesa portion 1A of the template 1 and the substrate portion 1D are not shown, and only a part of the second mesa portion 1B is shown.

As shown in FIG. 2A, the first mesa portion 1A, the second mesa portion 1B, and the substrate portion 1D have a substantially quadrangular plan view shape in the present embodiment. As shown in FIG. 2B, the first mesa portion 1A protrudes upward from substantially the center of the upper surface of the substrate portion 1D. The second mesa portion 1B protrudes upward from substantially the center of the upper surface of the first mesa portion 1A. As shown in FIG. 2A in a plan view, a lateral length of the first mesa portion 1A is about half of a lateral length of the substrate portion 1D, and a vertical length of the first mesa portion 1A is about half of a vertical length of the substrate portion 1D. A lateral width of the second mesa portion 1B is slightly smaller than a lateral width of the first mesa portion 1A, and a vertical width of the second mesa portion 1B is slightly smaller than a vertical width of the first mesa portion 1A.

The lateral width and the vertical width of the first mesa portion 1A and the second mesa portion 1B shown in FIG. 2A are one example, and sizes thereof are not particularly limited as long as the sizes are smaller than the substrate portion 1D.

The upper end surface of the second mesa portion 1B is a patterned surface 1a including an uneven portion corresponding to a pattern to be formed by a resist. The patterned surface 1a of the second mesa portion 1B has a rectangular shape that is long in a plan view as shown in FIG. 2A. The entire patterned surface 1a (entire upper end surface) of the second mesa portion 1B corresponds to an imprinting region e (also referred to as a shot region: see FIG. 2B) in the coating layer 2.

In the periphery of the second mesa portion 1B in the plan view, the outer peripheral portion of the first mesa portion 1A is disposed in a quadrangular frame shape having a constant width, and a light-shielding portion S configured with a light transmission limiting film is formed on the surface of the outer peripheral portion.

The light-shielding portion S may be formed by coating with a metal or the like, for example. As the material constituting the light-shielding portion S, for example, a material including one or more of a metal material, an oxide thereof, a nitride thereof, and an oxynitride thereof may be used. Specific examples of the above-described metal materials include chromium (Cr), molybdenum (Mo), tantalum (Ta), tungsten (W), zirconium (Zr), titanium (Ti), and the like.

It is possible that the light-shielding portion S shield the transmission of light (ultraviolet rays), by forming the light-shielding portion S with these materials. It is preferable that a the light-shielding portion S has transmittance of 10% or less in a case of being irradiated with ultraviolet rays having a wavelength of 365 nm.

In the present embodiment, the second mesa portion 1B is smaller than the first mesa portion 1A in a plan view and is concentrically disposed with the first mesa portion 1A as shown in FIG. 2A. That is, in a plan view, the center of the second mesa portion 1B and the center of the first mesa portion 1A may coincide with each other, and each side of the second mesa portion 1B may be parallel to a corresponding side of the first mesa portion 1A.

In the present embodiment, as shown in FIG. 2A, the shape of the light-shielding portion S in a plan view is a quadrangular frame shape surrounding the second mesa portion 1B having a quadrangular shape in a plan view with an equal width. The shape of the light-shielding portion S shown in the plan view of FIG. 2A is an example, and is not limited to the shape shown in FIG. 2A.

The patterned surface 1a of the second mesa portion 1B has an uneven portion for transfer in the imprint method on substantially the entire surface, and the characteristic points of the patterned surface 1a are as follows.

First, in the inner side 1e excluding an outer peripheral portion 1f of the patterned surface 1a in a plan view, an uneven portion of a standard pattern in which a desired uneven pattern is formed is formed.

In addition to the plurality of standard projection portions 1g for forming the desired standard uneven pattern, a plurality of dummy projection portions 1h for adjusting the pattern density are formed on the outer peripheral portion 1f of the patterned surface 1a. The width of the outer peripheral portion 1f is, for example, 5 mm or less, and it is possible to select the outer peripheral portion 1f having a constant width. In an inner side 1e excluding the outer peripheral portion 1f of the patterned surface 1a, the dummy projection portion 1h may not be provided or may be provided.

The standard projection portion 1g is, for example, a pattern corresponding to a device pattern (also referred to as a real pattern) after imprinting, and is based on design data and the like. The dummy projection portion 1h (also referred to as a dummy pattern) is a pattern corresponding to a configuration that is designed based on pattern information of the standard projection portion 1g and the like, as will be described later, and does not contribute to the function of the semiconductor device. That is, the pattern formed on the target film 6 by the dummy projection portion 1h may have an electrically floating state in which the pattern is not connected to a via, a wiring, or the like. The standard projection portion 1g and the dummy projection portion 1h may be any pattern such as a line and space shape, a pillar shape, or a hole shape.

Hereinafter, the pattern of the template 1 designed using the pattern design method of the template in the present embodiment will be described.

The outer peripheral portion 1f assumed in the present embodiment has a constant width, and in the example shown in FIG. 3, is divided along the outer periphery of the patterned surface 1a with a width of about one-several of the lateral length or of about one-several of the vertical length of the patterned surface 1a having a vertically long rectangular shape in the plan view. In the configuration illustrated in FIG. 3 in the present embodiment, as an example, the width W of the outer peripheral portion 1f is divided into approximately one-seventh of the lateral length of the patterned surface 1a and approximately one-ninth of the vertical length of the patterned surface 1a for easy viewing of the drawing.

Therefore, as illustrated in FIG. 3, the outer peripheral portion 1f is divided into seven quadrangular small regions 1i in the lateral direction and nine quadrangular small regions 1i in the vertical direction. In all the small regions 1i in the outer peripheral portion 1f, the dummy projection portions 1h are formed in each small region 1i in a number or an area necessary for each small region 1i such that a pattern density of all the standard projection portions 1g and the dummy projection portions 1h present in each small region 1i with respect to the area of each small region 1i falls within the first range. It is noted that FIG. 3 is an example, and the width of one side of the small region 1i and the number of small regions 1i are not particularly limited.

Here, the pattern density includes an area ratio or a volume ratio. In the present embodiment, the ratio of the total area of all the standard projection portions 1g and the dummy projection portions 1h present in each small region 1i with respect to the area of each small region 1i can be defined as an area ratio of the projection portion in each small region 1i. In the present embodiment, the dummy projection portion 1h having the required number or the required size is formed in each small region such that the pattern density of all the small regions 1i falls within the first range. The volume ratio will be described in detail in a modification example to be described later.

Since there are various patterns of the uneven pattern formed on the outer peripheral portion 1f, there are also various patterns of the uneven pattern formed in each small region 1i, and a position, the number, an inner diameter/width of the projection portion, and the like of the standard projection portion 1g formed in each small region 1i are also freely selected.

In the template 1 shown in FIG. 1A, for the sake of simplicity of illustration, only two adjacent small regions 1i among the plurality of small regions 1i formed in the second mesa portion 1B are displayed on the lower surface left side and the lower surface right side of the second mesa portion 1B.

Although there are various forms of the size, the number, the formation position, the formation interval, and the like of the standard projection portions 1g formed in the two adjacent small regions 1i, in order to easily understand in FIG. 1A, a pillar-shaped uneven pattern in which three standard projection portions 1g having small diameter protrude downward at predetermined intervals is shown as a representative example in the small region 1i on the lower surface left side in the second mesa portion 1B. Further, as a representative example, a pillar-shaped uneven pattern in which two dummy projection portions 1h having a small diameter protrude downward between three standard projection portions 1g is shown.

In the aspect shown in FIG. 1A, the standard projection portion 1g and the dummy projection portion 1h are, for example, projection portions having the same shape with the same inner diameter and the same height, and the standard projection portion 1g and the dummy projection portion 1h alternately protrude at constant intervals along the left-right direction of FIG. 1A.

In the aspect shown in FIG. 1A, the standard projection portion 1g is formed to an extent that the dummy projection portion 1h can be provided therebetween. Therefore, as an example, the standard projection portion 1g and the dummy projection portion 1h are drawn to have the same shape. However, the shapes and widths of each of the standard projection portions 1g may not be the same, and the shapes and widths of each of the dummy projection portions 1h may not be the same. In short, the pattern density of the projection portion in each small region 1i may be within the first range.

The dummy projection portion 1h is a projection portion formed in the outer peripheral portion 1f, and is a projection portion provided only for adjustment of the pattern density in a predetermined place where the standard projection portion 1g is not scheduled to be formed. It is preferable that the dummy projection portion 1h is dispersed as much as possible in each small region.

In the template 1 of FIG. 1A, a state where three standard projection portions 1n having a diameter larger than the previous standard projection portion 1g protrude downward at a predetermined interval in the small region 1i on the right side on the lower surface of the second mesa portion 1B is schematically shown. All the standard projection portions 1n on the lower surface right side of the second mesa portion 1B are drawn to have the same shape in order to make the drawing easy to see. However, in the standard projection portion 1n formed in the small region 1i, it is possible to adopt various heights, shapes in plan view, and the number of formations according to the uneven pattern to be formed, but FIG. 1A shows the standard projection portion 1n as an example.

In the second mesa portion 1B, in order to form the desired uneven pattern, the standard projection portions 1g and 1n having various shapes are provided in the small region 1i on the lower surface left side and the small region 1i on the lower surface right side. And in any small region 1i, it is preferable that the pattern density of the projection portions falls within the first range. For example, in the template 1 shown in FIG. 1A, the pattern density (area occupancy rate) of all the standard projection portions 1g with respect to the area of the small region 1i on the lower surface left side is 25%, and the pattern density (area occupancy rate) of all the dummy projection portion 1h is 25%. In addition, the pattern density (area occupancy rate) of all the standard projection portions 1n with respect to the area of the small region 1i on the lower surface right side is 50%. In this example, the design is made such that the pattern density of all the projection portions in both the left and right small regions 1i is completely equal.

Here, the above-mentioned pattern density falling within the first range means that, in the plurality of small regions 1i, for example, the pattern density of the small region 1i having the highest pattern density is used as a reference, and the pattern density of all the small regions 1i is in a range of ±10% of the reference. The first range is more preferably ±5%. Furthermore, in both the small regions 1i, it is most preferable that the pattern density is completely the same. It is noted that the pattern density to be used as a reference is not limited to the pattern density of the small region 1i having the highest pattern density, and may be a pattern density set as appropriate.

In other words, in the second mesa portion 1B shown in FIG. 1A, the pattern density is 50%, which is a ratio of the area occupied by the standard projection portion 1g and the dummy projection portion 1h with respect to the area of the small region 1i on the lower surface left side in the above-described example. In addition, in the second mesa portion 1B, the pattern density is 50%, which is a ratio of the area occupied by the standard projection portion 1n with respect to the area of the small region 1i on the lower surface right side.

In the small region 1i on the lower surface left side of the second mesa portion 1B, the pattern density of only the standard projection portion 1g excluding all the dummy projection portions 1h is 25%. In other words, in this small region 1i on the lower surface left side, it can be described that the dummy projection portion 1h having the pattern density of 25% is added to make the pattern density of 25% of only the standard projection portion 1g equal to the pattern density of 50% of the adjacent small region 1i on the right side.

The dummy projection portion 1h is designed based on pattern information of the standard projection portion 1g, and the position where the dummy projection portion 1h is formed is a region where the standard projection portion 1g is not formed, and is a region where the formation of the dummy projection portion 1h does not interfere with the device pattern in the post-processing. In other words, it is assumed that the imprint method is performed to form the uneven pattern including the dummy projection portions 1h on the coating layer 2 and the target film 6 is processed such as etching using the uneven pattern. In this case, it is preferable to form the dummy projection portion 1h at a position where the dummy projection portion 1h does not adversely affect the processing performed on the target film 6 by using the uneven pattern formed by the standard projection portion 1g.

FIG. 1B shows a second mesa portion 1B′ having a small region 1i in which only the standard projection portion 1g is provided with a pattern density of 25%. In the second mesa portion 1B′ shown in FIG. 1B, a standard projection portion 1n is formed in the small region 1i on the lower surface right side such that the pattern density is 50%, as in the second mesa portion 1B shown in FIG. 1A. A template 10 including a second mesa portion 1B′ shown in FIG. 1B corresponds to a comparative example.

In the template 1 of FIG. 1A, only two small regions 1i adjacent to each other on the patterned surface 1a of the second mesa portion 1B are shown and described. However, in the template 1 illustrated in FIG. 3, 28 small regions 1i are provided in the outer peripheral portion 1f. Nine small regions 1i are provided on the long side of the outer peripheral portion 1f, and seven small regions 1i are provided on the short side of the outer peripheral portion 1f. Since the small regions 1i at the intersection portion between the long side and the short side are common, a total of 28 small regions 1i are provided.

As an example, the pattern densitys are set to M % which is the same value in all of the 28 small regions 1i. The M % means the pattern density (%) of the small region 1i having the highest pattern density in only the standard projection portion in all of the 28 small regions 1i.

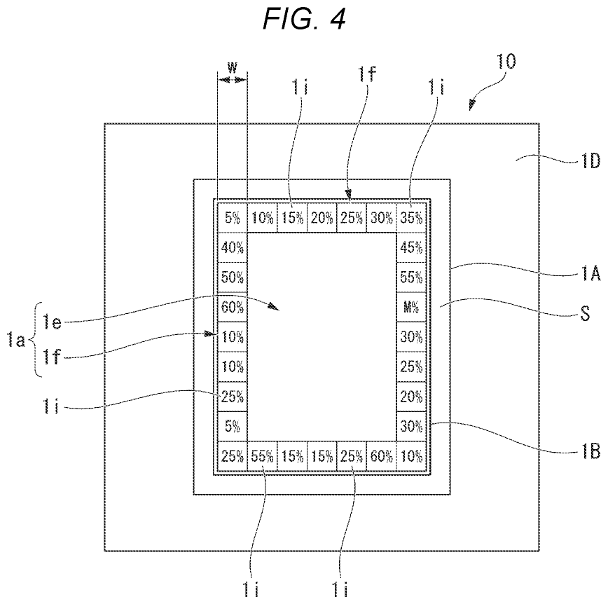

As an example, in FIG. 4, the pattern density of only the standard projection portion is shown for each of the 28 small regions 1i. In FIG. 4, in the outer peripheral portion 1f having a quadrangular frame shape in a plan view, the pattern density of the standard projection portion in the small region 1i located in the lower left corner portion is 25%, and the pattern density of each small region 1i arranged in sequence in the clockwise direction from the small region as a starting point is shown below.

In FIG. 4, the pattern densitys of the respective small regions 1i are set to 25%, 5%, 25%, 10%, 10%, 60%, 50%, 40%, 5%, 10%, 15%, 20%, 25%, 30%, 35%, 45%, 55%, M %, 30%, 25%, 20%, 30%, 10%, 60%, 25%, 15%, 15%, and 55% in this order.

Here, when the M& is the maximum pattern density of the standard projection portion, as shown in FIG. 3, the dummy projection portion 1h is provided in each small region 1i such that the pattern densitys in all the small regions 1i fall within the first range with respect to the M %.

For example, when M % is 70%, in order for the dummy projection portions 1h to be added to each small region 1i such that the pattern density is 70% in all the small regions 1i, the dummy projection portions 1h are provided such that the pattern densitys become as shown below in each small region 1i described in the above order.

In FIG. 4, the dummy projection portion 1h may be provided in each small region 1i in the order of 45%, 65%, 45%, 60%, 60%, 10%, 20%, 30%, 65%, 60%, 55%, 50%, 45%, 40%, 35%, 25%, 15%, 0%, 40%, 45%, 50%, 40%, 60%, 10%, 45%, 55%, 55%, and 15%.

In the template used in the practical nanoimprint method, the above-mentioned small region 1i can be defined as, for example, a small region divided into a mesh shape of 1 μm×1 μm in size. The size of the small region 1i is not limited to the size described so far, and can be appropriately set to a necessary size in a range of 1 μm×1 μm to 500 μm×500 μm. The small region 1i may have a square shape or a rectangular shape in a plan view.

In addition, the shape in a plan view of the dummy projection portion 1h provided in the small region 1i may be any shape such as a circle, a square, or a rectangle, and may be a more complicated figure or a polygonal shape.

### Method for Producing Template

In the template 1 of the embodiment, pattern information of the template is determined using the pattern design method of the embodiment described above. A pattern is formed in a resist or the like formed on a substrate based on the determined pattern information of the template, and the substrate is processed based on the pattern, thereby manufacturing the template 1 having the standard projection portion and the dummy projection portion 1h.

### Imprint Method

A method of imprinting the coating layer 2 using the template 1 described above will be described below. The imprint method may be performed, for example, as a part of a method for manufacturing a semiconductor device.

The substrate 5 including the coating layer 2 and the target film 6 described above is prepared using FIG. 1A. The coating layer 2 is applied to the entire upper surface of the predetermined target film 6 to be etched formed on the substrate 5, for example, by a spin coating method at a certain thickness. The coating layer 2 is, for example, ultraviolet curable (photocurable), and is a layer that is cured in a case of being irradiated with ultraviolet rays (light), but is in a liquid state in a case of being coated.

The template 1 with the patterned surface 1a facing downward is lowered onto the coating layer 2 from above the coating layer 2, and the uneven pattern formed on the patterned surface 1a of the template 1 is pressed against the coating layer 2 as shown in FIG. 1C.

At the time of imprinting, the uneven pattern is pressed against the coating layer 2 in a liquid state such that all the uneven portions are sunk in the coating layer 2 as shown in FIG. 1C.

While pressing the template 1 against the coating layer 2, light (for example, ultraviolet rays) is applied to the coating layer (resist layer) 2 from above the pattern 1C through the template 1 as indicated by the arrow. A range irradiated with the ultraviolet rays is a range surrounded by a quadrangular frame-shaped light-shielding portion S and the inside of the light-shielding portion S. The resist is cured by irradiation with ultraviolet rays, and the uneven pattern of the patterned surface 1a is transferred to the coating layer 2 as the necessary pattern PA. For example, a process of detaching a bottom portion of the pattern PA formed in the coating layer 2 to expose the target film 6 is performed. Next, the target film 6 is etched using the coating layer 2 as a mask. As a result, a pattern corresponding to the pattern PA is formed on the target film 6. The remaining coating layer 2 is detached by, for example, an ashing process. After that, for example, when the target film 6 is an insulating layer, a metal such as copper (Cu) is embedded in a pattern formed on the target film 6, and becomes, for example, a part of a dual damascene wiring.

Since the template 1 shields the ultraviolet rays with the light-shielding portion S having a quadrangular frame shape in a plan view, only the coating layer 2 located on the inside and below the light-shielding portion S can be cured. In the template 1, the lower region of the patterned surface 1a of the second mesa portion 1B is a region necessary for imprinting.

In this case, when the imprinting is performed using the template 1 shown in FIGS. 1A to 3, the uneven pattern of the patterned surface 1a of the second mesa portion 1B is pressed against the coating layer 2. Therefore, the plurality of standard projection portions 1g and 1n present on the patterned surface 1a extrude the resin of the coating layer 2 to the periphery, and the dummy projection portion 1h also extrudes the resin to the periphery. By extruding these resins, a surplus resin is extruded to the outside of the outer periphery of the patterned surface 1a.

However, in the template 1 of the present embodiment, in the outer peripheral portion 1f of the patterned surface 1a, the necessary number of dummy projection portions 1h are provided for each small region 1i, and the pattern densitys of the projection portions in the outer peripheral portion 1f is set to be in the same range, as shown in FIG. 3. Therefore, an amount of the surplus resin extruded to the periphery of the patterned surface by the patterned surface 1a of the second mesa portion 1B, can be made uniform at the outer peripheral portion of the patterned surface 1a. For example, as shown in FIG. 1C, the amounts of the surplus resin 2a extruded to the outer peripheral side on the lower surface left side of the second mesa portion 1B and the surplus resin 2b extruded to the lower surface right side can be made uniform.

When the amount of the surplus resin can be made uniform, the amount of the surplus resin can be reduced, and thus a desired pattern having a well-arranged uneven shape without defects such as pattern filling can be obtained by the imprint method using the template 1.

It is likely that the surplus resin is occurred when the pattern density of the template 1 is non-uniform on the patterned surface 1a. A mechanism thereof will be described below.

An uneven pattern having a high pattern density requires a small amount of resin to be filled, and an uneven pattern having a low pattern density requires a large amount of resin to be filled.

In a spin-coating type nanoimprint, since the amount of resin on the entire surface of the substrate is uniform, it is needed that the coating film thickness is determined such that the uneven pattern having a low pattern density is filled with the resin of the coating layer 2.

In this case, in the uneven pattern having a high pattern density, the resin is supplied excessively, therefore a surplus resin is occurred. In order to prevent the occurrence of the surplus resin as much as possible, it is important to make the pattern density of each small region 1i in the outer peripheral portion of the patterned surface 1a substantially uniform.

Therefore, when the imprint method using the template 1 having the above-described configuration is performed, the amount of the surplus resin can be reduced by substantially uniformizing the amount of the surplus resin in the outer peripheral portion of the patterned surface 1a.

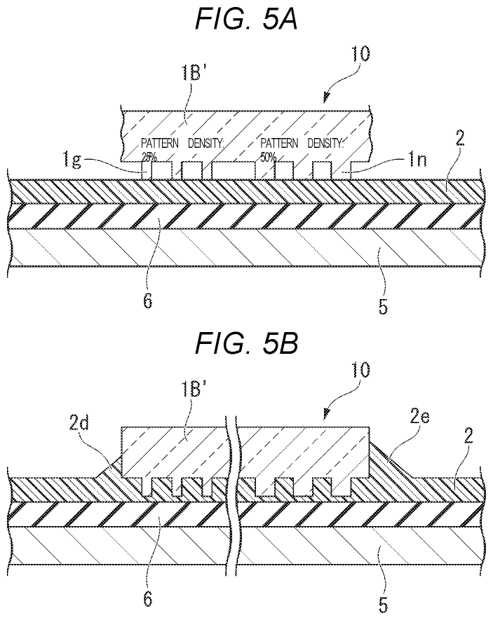

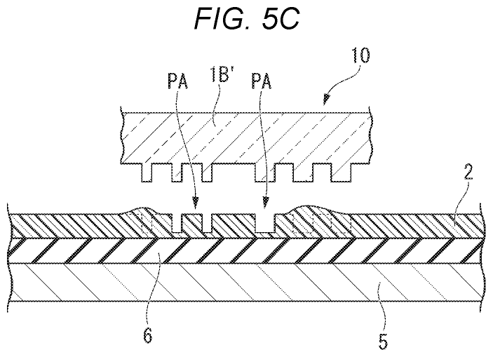

Conversely, when the second mesa portion 1B′ shown in FIG. 1B of the comparative example is used as the template 10 and the coating layer 2 is imprinted, the pattern density of the projection portion is greatly different depending on the position in the outer peripheral portion of the patterned surface 1a. Therefore, as shown in FIGS. 5A and 5B, the amount of the surplus resin protruding from the pattern PA is large at the position where the pattern density is high, depending on the pattern density of the projection portion, and the amount of the resin protruding is different at each position. For example, the amount of the surplus resin 2e occurred on the outer peripheral side of the lower surface right side is larger than the amount of the surplus resin 2d occurred on the outer peripheral side of the lower surface left side of the second mesa portion 1B.

In addition, a position where the surplus resin extruded to the outer peripheral side of the patterned surface 1a shown in FIG. 5B is present is a region where the light is shielded by the light-shielding portion S and the region is not irradiated with the light. Therefore, the surplus resin remains in a liquid state, and when the template 10 is lifted and released after exposure, the liquid surplus resin flows in a direction opposite to a case where the liquid surplus resin is extruded. Therefore, as shown in FIG. 5C after the release, the surplus resin may flow to fill a part of the cured pattern PA, and an uneven pattern having a shape defect such as pattern filling may be occurred.

A flow of the uneven pattern transfer according to an optical nanoimprint method, which is an example of an optical imprint method described above, includes, as an example, each of the following steps: 1. coating a photocurable resin, which is an imprint material, on a substrate to be processed; 2. alignment and pressing (contact) the substrate and a template;

3. curing the resin by light irradiation; 4. releasing and rinsing; and 5. detaching remaining film using anisotropic etching mainly by oxygen plasma.

### Modification Example

Meanwhile, in the template 1 described so far with reference to FIGS. 1A to 4, in the small region 1i divided in the outer peripheral portion 1f of the second mesa portion 1B, the necessary dummy projection portion 1h is formed according to the pattern density of the standard projection portions 1g and 1n present in each small region 1i as a solution to a problem.

As a solution to a problem of the present embodiment, the dummy projection portion with respect to the total volume of the standard projection portion 1g or the standard projection portion 1n present in each small region 1i without being limited to the pattern density may be provided.

For example, in the above-described embodiment, in each small region 1i, the pattern density M % shown in FIG. 3 is described as the total area (area ratio) of all the standard projection portions 1g and all the dummy projection portions 1h with respect to the area of each small region 1i.

In addition, it was described that the pattern density M % is equal to an area ratio (%) of the small region 1i having the highest pattern density in all the small regions 1i, and the pattern density is the total area ratio of the plurality of standard projection portions 1n in the small region 1i having the highest pattern density.

In the template of the present modification example, the pattern of the template is designed with the total volume of the standard projection portions 1g or the standard projection portions 1n present in the small region 1i as a reference. In this case, regarding the pattern density M % shown in FIG. 3, the pattern density M % can be replaced with the sum of total volume of all the standard projection portions 1g volume and the total dummy projection portion 1h volume with respect to the area of each small region 1i in each small region 1i.

In addition, the pattern density M % of the above embodiment can be reinterpreted as a volume equal to the total volume of all the projection portions in the small region 1i having the highest total volume of all the projection portions in all the small regions 1i. In addition, the value of the total volume of all the projection portions can be described as being equal to the total volume of all the standard projection portions 1n formed in the small region 1i having the highest total volume of all the projection portions.

Therefore, in the present modification example, as an example, in all of the 28 small regions 1i shown in FIG. 3, the total volume of all the projection portions is set to M μm³ having the same value. As an example, the M μm³ means a total volume of all the standard projection portion of the small region having the highest total volume of all the projection portion among the small regions in which a volume of all the standard projection portions of the 28 small regions 1i is compared.

Similar to the case of description based on FIG. 4, the total volume of all the standard projection portions is different for each of the 28 small regions 1i.

Therefore, the total volume of all standard projection portions is adjusted to fall within the first range by providing the necessary number of dummy projection portions 1h for each total volume of all the projection portions of the other small regions 1i such that the total volume of all the standard projection portions is in agreement with the total volume of all standard projection portions in the region where the total volume of all standard projection portions is largest in all small regions 1i.

As a result, in all the 28 small regions 1i, the total volume of all the projection portions can be adjusted to be substantially equal to each other.

Similarly, for the volume-based template, the pattern density is in the first range, which means that, for example, the total volume of all the small regions 1i is within a range of ±10% based on the small region 1i having the highest total volume. The first range is more preferably within a range of ±5%. Furthermore, it is most preferable that the total volumes in all the small regions 1i are substantially the same.

In other words for this example, in the second mesa portion 1B shown in FIG. 1A, the total volume occupied by all the standard projection portions 1g and all the dummy projection portions 1h in the small region 1i on the lower surface left side is set to M μm³. In addition, in the small region 1i on the lower surface right side of the second mesa portion 1B, the volume occupied by all the standard projection portions 1n is also M μm³.

In the case of the volume-based template, an amount of the surplus resin extruded to the periphery by the patterned surface 1a of the second mesa portion 1B can be substantially uniformized at the outer peripheral portion of the patterned surface 1a, similar to the template 1 in which the pattern density (%) is defined above.

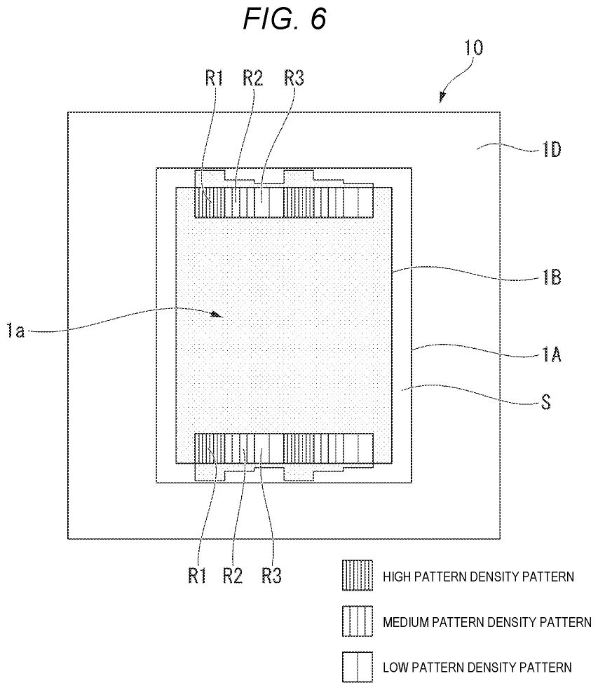

As shown in FIG. 6, when the dummy projection portion 1h is not provided, a state in which a relatively large amount of surplus resin is occurred is shown in a high pattern density patterned region R1 of having a high pattern density of the projection portion on the outer peripheral side of the patterned surface 1a. Similarly, in a medium pattern density patterned region R2, a small amount of surplus resin is occurred as compared with the region R1, and in a low pattern density patterned region R3, a small amount of surplus resin is occurred as compared with the region R2.

Since these surplus resins are extruded to the periphery of the region in which the light-shielding portion S is formed, the surplus resins remain as a liquid without being cured with light (ultraviolet rays).

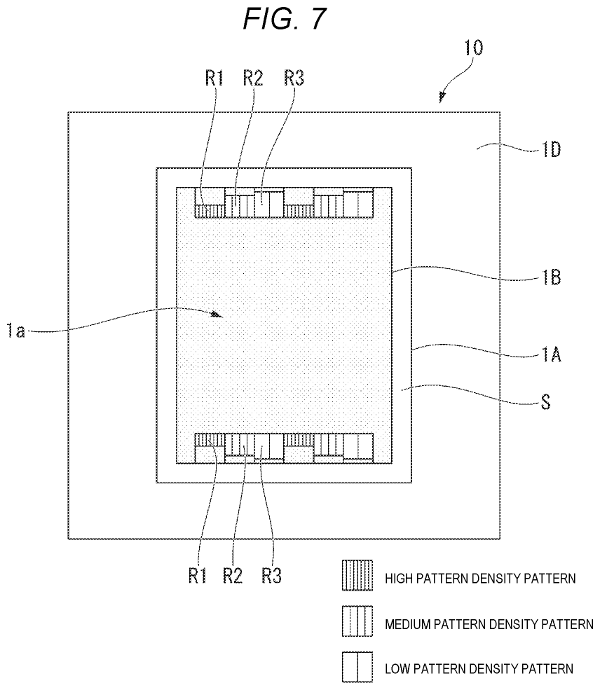

FIG. 7 is a plan view showing a comparison of the amount of the surplus resin flowing to the uneven pattern side in the region R1, the amount of the surplus resin flowing to the uneven pattern side in the region R2, and the amount of the surplus resin flowing to the uneven pattern side in the region R3, after the template 10 of FIG. 6 is released from the coating layer 2.

As shown in FIG. 7, a case where the amounts of the surplus resin are different depending on the regions R1, R2, and R3 is considered. Conversely, when the above-mentioned template 1 is applied, the amount of the surplus resin can be made substantially uniform and reduced.

### Second Embodiment

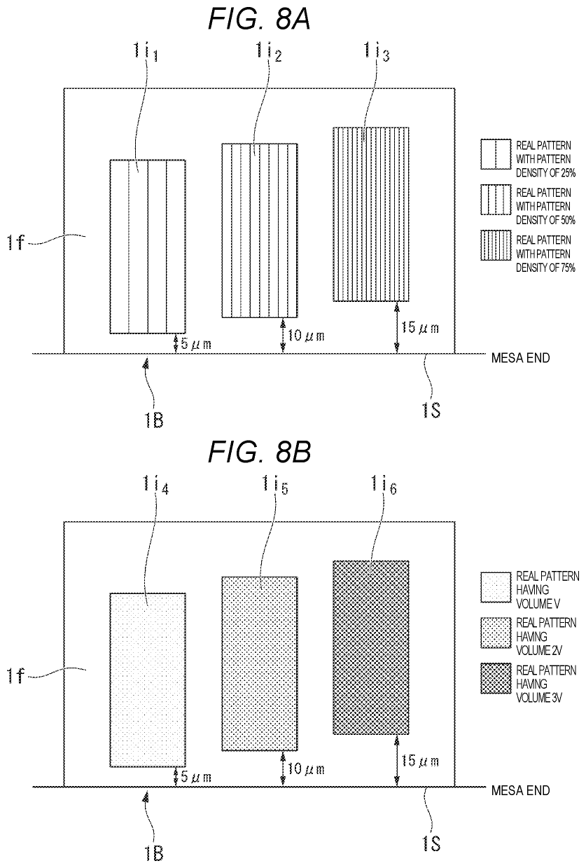

FIG. 8A shows an example of a disposition of a small region 1 in having a pattern density of 25%, a small region 112 having a pattern density of 50%, and a small region 1i₃ having a pattern density of 75%, all having a quadrangular shape in a plan view. This disposition example is an example when the small region 1i₁, the small region 1i₂, and the small region 1i₃ are disposed on the outer peripheral portion 1f of the patterned surface 1a of the second mesa portion 1B. In the present embodiment, each of the plurality of small regions 1i₁, the small region 1i₂, and the small region 1i₃ has a plurality of real patterns. Here, the pattern density includes an area ratio or a volume ratio.

In this example, the small region 1i is disposed at a position, for example, 5 μm away from the outer peripheral edge 1s of the patterned surface 1a, the small region 1i2 is disposed at a position, for example, 10 μm away from the outer peripheral edge 1s of the patterned surface 1a, and the small region 1i₃ is disposed at a position, for example, 15 μm away from the outer peripheral edge 1s of the patterned surface 1a. The position away from the outer peripheral edge 1s adopted in this example is a distance in which the side close to the outer peripheral edge 1s in each small region is separated from the straight line indicating the outer peripheral edge 1s of the patterned surface 1a in the direction perpendicular to the straight line by the above-mentioned distance.

The configuration shown in FIG. 8A is a configuration in which a magnitude relationship of (the amount of the surplus resin occurred in the small region 1i, having a pattern density of 25%)<(the amount of the surplus resin occurred in the small region 1i₂ having a pattern density of 50%)<(the amount of the surplus resin occurred in the small region 1i₃ having a pattern density of 75%) is taken into account. That is, in the plurality of small regions 1i₁, the small region 112, and the small region 1i₃, the pattern density in each small region is calculated, and the distance of separation from the outer peripheral edge 1s is determined based on the calculated pattern density.

That is, the small region 1i₃ having the largest amount of the surplus resin is disposed at the position farthest from the outer peripheral edge 1s according to the magnitude of the amount of the surplus resin expected to be occurred in each of the small region 1i₁, the small region 1i₂, and the small region 1i₃. The small region 1i₂ having the second largest amount of the surplus resin is disposed at a position second farthest from the outer peripheral edge 1s. The small region 1i₁ having the third largest amount of the surplus resin is disposed at a position third away from the outer peripheral edge 1s.

Since the small regions 1i₁, 1i₂, and 1i₃ are disposed in this way, even if the surplus resin is occurred in each small region, the surplus resin cannot be extruded out to the outside of the outer peripheral edge 1s. Alternatively, when the surplus resin is extruded to out to the outside of the outer peripheral edge 1s, the amount of the resin to be extruded can be minimized as much as possible, and the extrusion amount can be adjusted such that the uneven pattern is not filled.

As an example, when forming a wiring portion on a substrate using the current dual damascene technology, the small region 1i is assumed to be a mesh of 1 μm size, and the imprint method is performed using a template with a pattern density of 46% or more using nanoimprint technology. The present inventors have found that when a template having a normal uneven pattern is used, an unfilled defect that the uneven pattern cannot be filled with the resin of the coating layer does not occur. Therefore, when the pattern density of the projection portion is to be aligned in the template 1, it is desirable that the pattern density of all the projection portions of the small regions 1i is aligned in the small regions 1i having a filling rate of 46% or more.

In FIG. 8B, for example, when the pattern density is calculated by volume ratio and the total volume of the projection portions in the small region 1i₄ is denoted V, the total volume of the projection portions in the small region 115 is denoted 2V, and the total volume of the projection portions in the small region 1i₆ is denoted 3V, a desirable disposition example of the small region 1i₄, the small region 1i₅, and the small region 1i₆ with respect to the outer peripheral edge 1s of the second mesa portion 1B is shown.

In the configuration shown in FIG. 8B, the disposition is adopted according to the magnitude of the amounts of the surplus resin expected to be occurred in each of the small region 114, the small region 1i₅, and the small region 1i₆. The end edge of the small region 1i₆ having the largest surplus resin amount is disposed at a position farthest from the outer peripheral edge 1s. The end edge of the small region 1i₅ having the second largest surplus resin amount is disposed at a position second farthest from the outer peripheral edge 1s. The end edge of the small region 1i₄ having the third largest amount of the surplus resin is disposed at a position third away from the outer peripheral edge 1s.

In this example, the end edge of the small region 1i₄ is disposed at a position, for example, 5 μm away from the outer peripheral edge 1s of the patterned surface 1a. The end edge of the small region 1i₅ is disposed at a position, for example, 10 μm away from the outer peripheral edge 1s of the patterned surface 1a. The end edge of the small region 1i₆ is disposed at a position, for example, 15 μm away from the outer peripheral edge 1s of the patterned surface 1a.

The configuration shown in FIG. 8(B) is a configuration in which a relationship of (the amount of the surplus resin occurred in the small region 1i₄ having the total volume V of the projection portions)<(the amount of the surplus resin occurred in the small region 1i₅ having the total volume 2V of the projection portions)<(the amount of the surplus resin occurred in the small region 1i₆ having the total volume 3V of the projection portions) is taken into account. That is, in the plurality of small regions 1i₄, the small region 1i₅, and the small region 1i₆, the total volume in each small region is calculated, and the distance at which the end edge of each region is separated from the outer peripheral edge 1s is determined based on the calculated total volume.

The end edge of the small region 1i₆ having the largest amount of the surplus resin is disposed at the position farthest from the outer peripheral edge 1s according to the magnitude of the amount of the surplus resin expected to be occurred in each of the small region 1i₄, the small region 1i₅, and the small region 1i₆. The end edge of the small region 1i₅ having the second largest surplus resin amount is disposed at a position second farthest from the outer peripheral edge 1s. The end edge of the small region 1i₄ having the third largest amount of the surplus resin is disposed at a position third away from the outer peripheral edge 1s.

Since each small region is disposed in this way, even if the surplus resin is occurred, the surplus resin cannot be extruded out to the outer peripheral edge 1s. Alternatively, when the surplus resin is extruded out to the outer peripheral edge 1s, the amount of the surplus resin to be extruded can be minimized as much as possible, and so that the uneven pattern is not filled.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

In addition, the template 1 of the embodiment described above and the modification example thereof can be widely applied to an imprint method of transferring a mold (template) of an original plate to a substrate as a technique for forming a fine pattern with high productivity in the production of an electronic device or a magnetic recording medium having a microstructure such as a semiconductor device, a micro electro mechanical system (MEMS) device, or a magnetic recording device.

What is claimed is:

1. A pattern formation method, comprising:
dividing an outer peripheral portion of a patterned surface including a device pattern into a plurality of regions along a circumferential direction; and
disposing a dummy pattern in the outer peripheral portion, causing a pattern density of each of the plurality of regions to fall within a first range based on information regarding the device pattern.

2. The pattern design method according to claim 1, wherein the pattern density includes an area ratio or a volume ratio.

3. The pattern design method according to claim 1, wherein the first range is ±10% with respect to a pattern density of at least one of the plurality of regions.

4. The pattern design method according to claim 3, wherein the at least one region has a highest pattern density among the plurality of regions.

5. A pattern formation method, comprising:
dividing an outer peripheral portion of a patterned surface including a pattern into a plurality of regions along a circumferential direction;
calculating a pattern density of each of the plurality of regions; and
determining a distance between an outer peripheral edge of the patterned surface and an end edge of each of the plurality of regions based on the calculated pattern density.

6. The pattern design method according to claim 5, wherein the pattern density includes an area ratio or a volume ratio.

7. A method for manufacturing a template, comprising:
dividing an outer peripheral portion of a patterned surface including a device pattern and a dummy pattern into a plurality of regions along a circumferential direction;
disposing the dummy pattern in the outer peripheral portion, causing a pattern density of each of the plurality of regions to fall within a first range based on information regarding the device pattern;
deriving pattern information of a template through the dividing and the disposing; and
forming the device pattern and the dummy pattern in the patterned surface based on the derived pattern information.

8. The pattern design method according to claim 5, wherein the plurality of regions includes a first region and a second region where the pattern density is higher than the first region;
the distance of the second region is longer than distance of the first region.
